(19) United States
(12) Patent Application Publication
(10) Pub. No.: US 2014/0238952 A1
(43) Pub. Date: Aug. 28, 2014

(54) METHOD FOR MANUFACTURING THIN SUBSTRATE

(71) Applicant: SHARP KABUSHIKI KAISHA, Osaka (JP)

(72) Inventors: Hiroki Makino, Osaka (JP); Gen Nagaoka, Osaka (JP); Takatoshi Kira, Osaka (JP)

(73) Assignee: SHARP KABUSHIKI KAISHA, Osaka (JP)

(21) Appl. No.: 14/352,665

(22) PCT Filed: Oct. 15, 2012
(86) PCT No.: PCT/JP2012/006594

§ 371 Date: Apr. 17, 2014

(30) Foreign Application Priority Data
Oct. 20, 2011 (JP) 2011-230775

(51) Int. Cl. B81C 1/00

(52) U.S. Cl. CPC B81C 1/00523
USPC 216/2

(57) ABSTRACT

A method for manufacturing a thin substrate includes the following steps: a first etching step in which the thickness of a glass substrate (110a) is reduced by etching one surface of the glass substrate (110a); a scribing step in which a scribe line (Ca) for splitting a glass substrate (110b), which is formed by reducing the thickness of the glass substrate (110a), is formed on a surface of the glass substrate (110b); and a second etching step in which the thickness of a glass substrate (110c), which is formed by forming the scribe line (Ca) on the glass substrate (110b), is reduced by etching a surface of the glass substrate (110c), and the glass substrate (110c) is split by way of the scribe line (Ca).

### TECHNICAL FIELD

The present invention relates to a method of manufacturing a thin substrate, and in particular relates to a method of manufacturing a thin substrate that is a glass substrate.

### BACKGROUND ART

In recent years, in display devices such as liquid crystal display devices, technological development in thinning and lightening devices by thinning glass substrates, using film substrates instead of glass substrates, having a shared substrate, or the like has been vigorous.

For example, Patent Document 1 discloses a method of manufacturing a display panel in which scribe lines are formed in a large substrate and then chemical etching is performed on the large substrate, thereby thinning the large substrate and deepening the scribe lines.

Patent Document 2 discloses a mobile information device including: a flexible sheet constituting an upper substrate of a touch panel, an integral glass substrate having the function of both a lower substrate of the touch panel and an upper substrate of a liquid crystal panel, spacers provided between the flexible sheet and the integral glass substrate, a lower panel substrate that is a lower substrate of the liquid crystal panel, a liquid crystal layer sealed between the integral glass substrate and the lower panel substrate, an EL (electroluminescent) backlight that supplies light to the liquid crystal panel, an IC (integrated circuit) that applies a voltage to the liquid crystal panel, driver circuits that control the touch panel display device, and a flexible substrate on which the IC and the driver circuits are installed.

Patent Document 3 discloses a method of manufacturing a flexible glass substrate in which, after forming a pattern on one surface of a glass substrate, one surface of the glass substrate is temporarily attached to a supporting body, the other surface of the glass substrate etched and thereby thinned, a film substrate is bonded to the other surface of the glass substrate after etching, and the temporarily attached supporting body is removed from the one surface of the glass substrate.

### RELATED ART DOCUMENTS

### Patent Documents

Patent Document 1: Japanese Patent Application Laid-Open Publication No. 2007-298747
Patent Document 2: Japanese Patent Application Laid-Open Publication No. 2003-157148
Patent Document 3: Japanese Patent No. 4565670

### SUMMARY OF THE INVENTION

### Problems to be Solved by the Invention

However, according to the manufacturing method disclosed in Patent Document 1, while it is possible to thin the large substrate, because (chemical) etching is performed one or more times after forming the scribe lines in the large substrate, there is a risk that the scribe lines formed in the large substrate become filled with reaction products such as AlF₃, MgF₂, and CaF₂ resulting from etching. If this happens, during a breaking step during which the large substrate is mechanically split, it becomes difficult to split the large substrate into individual parts, and thus, there is room for improvement.

The present invention takes into account this problem, and an object thereof is to reliably split a thin glass substrate.

### Means for Solving the Problems

In order to achieve the above-mentioned object, in the present invention, a glass substrate is thinned in a first etching step before forming scribe lines in a surface of the glass substrate in a scribing step, and then, in a second etching step after the scribing step, the glass substrate is thinned and the glass substrate is split along the scribe lines.

Specifically, a method of manufacturing a thin substrate according to the present invention includes: a first etching step of etching one surface of a glass substrate and thereby thinning the glass substrate; a scribing step of forming a scribe line in a surface of the thinned glass substrate in order to split the glass substrate; and a second etching step of etching the surface of the glass substrate in which the scribe line is formed to thin the glass substrate and split the glass substrate along the scribe line.

According to the above-mentioned method, before forming the scribe lines for splitting the glass substrate in the surface of the glass substrate in the scribing step, one surface of the glass substrate is etched in the first etching step, which thins the glass substrate, and thus, in the second etching step, the amount of etching necessary in the glass substrate in order to split the glass substrate along the scribe lines is small. Thus, in the second etching step, when etching the surface of the glass substrate in which the scribe lines are formed, a situation in which reaction products from etching fill the scribe lines is mitigated, thus the glass substrate is split reliably along the scribe lines formed in the surface of the glass substrate. As a result, in the method of manufacturing the thin substrate, the glass substrate is reliably split, and thus, the thin glass substrate is reliably split.

Also, according to the method above, in the second etching step, the scribe lines formed in the surface of the glass substrate are enlarged, and thus, scratches in the scribe line in each glass substrate formed in the scribing step are lessened by etching, and thus, the edge faces of the respective split glass substrates are strengthened.

In the first etching step, a film may be attached to another surface of the glass substrate before etching the one surface of the glass substrate, in the scribing step, the scribe line may be formed in the one surface of the glass substrate, and a film-cutting step of cutting the film such that the film is provided for each of the separated glass substrates may be included after the second etching step.

According to the method above, in the first etching step, the film is attached to the other surface of the glass substrate before etching the one surface of the glass substrate, and thus, it is difficult to etch the other surface of the glass substrate. In the scribing step, the scribe lines are formed in the one surface of the glass substrate with the film being attached to the other surface of the glass substrate, and in the following second etching step also, the film is attached to the other surface of the glass substrate as the one surface of the glass substrate is etched, and thus, the glass substrate is split by the scribe lines with the respective split glass substrates being attached to the film. In the film-cutting step, the film is cut for each glass substrate separated during the second etching step, and thus, the film is separated for each individual glass substrate separated during the second etching step.

In the first etching step, before etching the one surface of the glass substrate but after the film is attached to the another surface of the glass substrate, a hard plate may be attached to the film, and a hard plate removal step of removing the hard plate may be included between the second etching step and the film-cutting step.

According to the method above, in the first etching step, the hard plate is attached to the film before the one surface of the glass substrate is etched and after the film is attached to the other surface of the glass substrate, and thus, by etching the one surface of the glass substrate in the first etching step, the shape of the glass substrate is maintained by the hard plate attached to the film even if the glass substrate is thinned. Also, in the second etching step, even if the glass substrate thinned during the first etching step is split, as a result of the hard plate attached to the film, the split glass substrates are separate from each other, thus mitigating damage to the respective glass substrates. The hard plate removal step of removing the hard plate is included between the second etching step and the film-cutting step, and thus, the film is cut during the film-cutting step without the hard plate being a physical obstruction.

The film and the hard plate may be formed so as to be larger than the glass substrate in a plan view, in the first etching step, the hard plate may be attached to the film by the film and the hard plate being bonded to each other outside of an edge of the glass substrate, and in the hard plate removal step, the hard plate may be removed by cutting off a bonding portion between the film and the hard plate.

According to the method above, the film and the hard plate are formed larger than the glass substrate in a plan view, and in the first etching step the hard plate is attached to the film by bonding the film and the hard plate outside of the edge of the glass substrate, and thus, in the hard plate removal step, by cutting off the bonding portion between the film and hard plate protruding from the edge of the glass substrate, the hard plate is removed with ease from the film attached to the other surface of the glass substrate.

An element layer forming step of forming a plurality of element layers respectively split along with the glass substrate in the second etching step on the another surface of the glass substrate may be included before the first etching step.

According to this method, the element layer forming step of forming the plurality of element layers respectively split along with the glass substrate in the second etching step on the other surface of the glass substrate is included before the first etching step, and thus, in the method of manufacturing the thin substrate provided with the element layer on the surface of the glass substrate, the glass substrate is reliably split.

The plurality of element layers may respectively be touch panel layers that function as touch panels.

According to the method above, the plurality of element layers are respectively touch panel layers functioning as touch panels, and thus, in the method of manufacturing the thin substrate provided with the touch panel layer on the surface of the glass substrate, the glass substrate can be reliably split.

The plurality of element layers may be reflection suppression films respectively formed integrally.

According to the method above, the plurality of element layers are reflection suppression films respectively formed integrally, and thus, in the method of manufacturing the thin substrate provided with the reflection suppression film on the surface of the glass substrate, the glass substrate is reliably split.

### Effects of the Invention

According to the present invention, the glass substrate is thinned in the first etching step before forming scribe lines in the surface of the glass substrate in the scribing step, and the glass substrate is thinned in the second etching step after the scribing step while the glass substrate is split along the scribing grooves, and thus, it is possible to split the thin glass substrate reliably.

### BRIEF DESCRIPTION OF THE DRAWINGS

FIG. 1 is a cross-sectional view of a touch panel substrate according to Embodiment 1.

FIG. 2 is a plan view of a touch panel layer included in the touch panel substrate according to Embodiment 1.

FIG. 3 is a cross-sectional view of the touch panel layer and the touch panel substrate including this along the line III-III in FIG. 2.

FIG. 4 is a flow chart for manufacturing the touch panel substrate of Embodiment 1.

FIG. 5 is a descriptive drawing showing cross-sections of a method of manufacturing the touch panel substrate according to Embodiment 1.

FIG. 6 is a cross-sectional view of a modification example of the touch panel substrate according to Embodiment 1.

FIG. 7 is a micrograph of an edge face of a glass substrate of an example of the touch panel substrate of Embodiment 1.

FIG. 8 is a micrograph of an edge face of a glass substrate of a comparison example of the touch panel substrate of Embodiment 1.

FIG. 9 is a cross-sectional view of a reflection suppression film substrate according to Embodiment 2.

FIG. 10 is a flow chart for manufacturing the reflection suppression film substrate according to Embodiment 2.

FIG. 11 is a cross-sectional view of a glass substrate according to Embodiment 3.

FIG. 12 is a flow chart for manufacturing the glass substrate according to Embodiment 3.

FIG. 13 is a descriptive drawing showing cross-sections of a method of manufacturing the glass substrate according to Embodiment 3.

### DETAILED DESCRIPTION OF EMBODIMENTS

An embodiment of the present invention will be described in detail below with reference to drawings. The present invention is not limited to the embodiments below.

### Embodiment 1

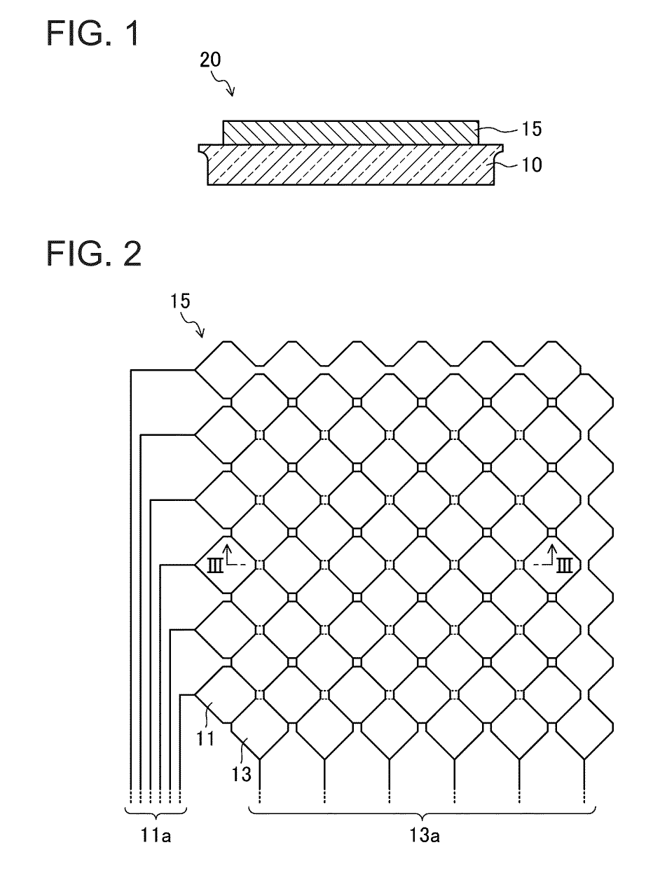

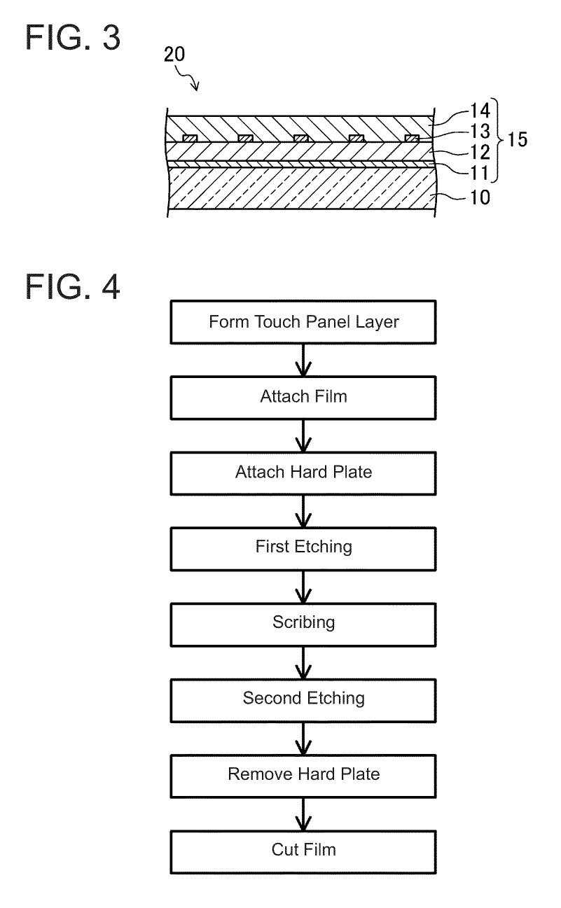

FIGS. 1 to 8 show Embodiment 1 of a method of manufacturing a thin substrate according to the present invention. Specifically, FIG. 1 is a cross-sectional view of a touch panel substrate 20 of the present embodiment. FIG. 2 is a plan view of a touch panel layer 15 included in the touch panel substrate 20, and FIG. 3 is a cross-sectional view of the touch panel layer 15 and the touch panel substrate 20 including this along the line III-III of FIG. 2.

As shown in FIGS. 1 and 3, the touch panel substrate 20 includes a glass substrate 10 and a touch panel layer 15 provided as an element layer on the glass substrate 10.

As shown in FIGS. 2 and 3, the touch panel layer 15, on the glass substrate 10, includes a plurality of first transparent electrodes 11 provided so as to extend in parallel with each other (in the horizontal direction of FIG. 2), an interlayer insulating film 12 provided so as to cover the respective first transparent electrodes 11, a plurality of second transparent electrodes 13 provided on the interlayer insulating film 12 so as to extend in parallel with each other in a direction perpendicular to the first transparent electrodes 11 (in the vertical direction in FIG. 2), and a protective insulating film 14 provided so as to cover the respective second transparent electrodes 13.

As shown in FIG. 2, the first transparent electrodes 11 are respectively formed such that a plurality of constituent units formed in substantially square shapes are connected to each other in one row at opposing corners, and a first lead-out wiring line 11a is connected to an end (left end in the drawing) of each of the first transparent electrodes 11.

As shown in FIG. 2, the second transparent electrodes 13 are respectively formed such that a plurality of constituent units formed in substantially square shapes are connected to each other in one row at opposing corners, and a second lead-out wiring line 13a is connected to an end (bottom end in the drawing) of each of the second transparent electrodes 13. Here, the second lead-out wiring lines 13a are formed in the same layer as the first transparent electrodes 11 and the first lead-out wiring lines 11a, and are connected to the second transparent electrodes 13 through contact holes (not shown) formed in the interlayer insulating film 12.

When the touch panel substrate 20 with the configuration above is touched at the surface of the touch panel layer 15, it is grounded by the capacitance formed with a human body at a position of each first transparent electrode 11 and each second transparent electrode 13 where touch has occurred, and this causes a change in capacitance between a position where touch has occurred and each first transparent electrode 11 and each second transparent electrode 13. At this time, a separately provided position detection circuit detects the touch position on the basis of currents flowing through each first lead-out wiring line 11a and each second lead-out wiring line 13a.

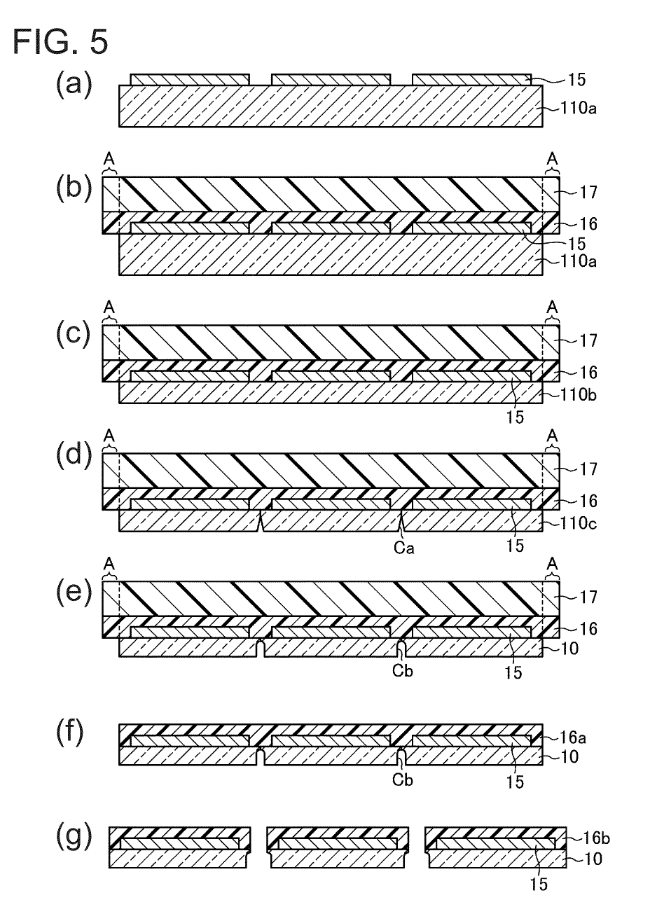

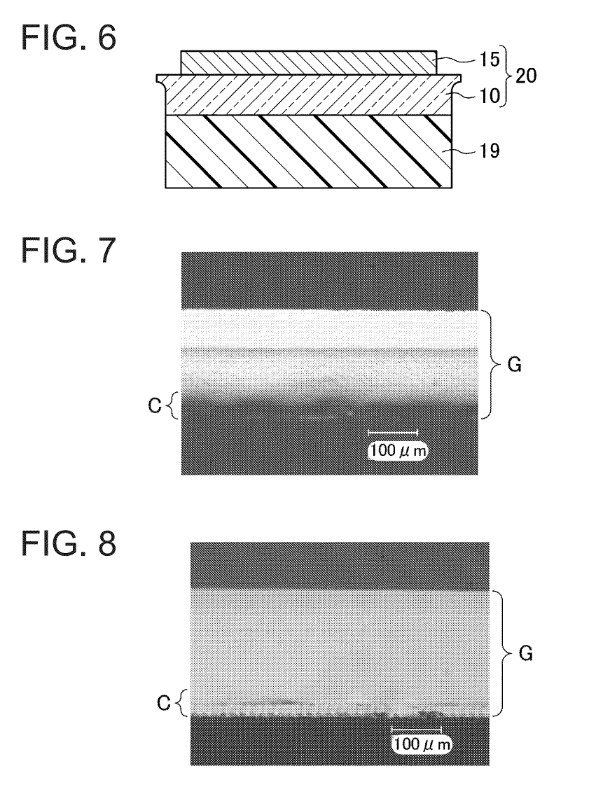

Next, a method of manufacturing the touch panel substrate 20 of the present embodiment will be described. FIG. 4 is a flow chart for manufacturing the touch panel substrate 20. FIG. 5 is a descriptive drawing showing cross-sections of a method of manufacturing the touch panel substrate 20. FIG. 6 is a cross-sectional view of a modification example of the touch panel substrate 20.

As shown in FIG. 4, the method of manufacturing the touch panel substrate 20 of the present embodiment includes a step of forming a touch panel layer, a first etching step including attaching a film and attaching a hard plate, a scribing step, a second etching step, a step of removing the hard plate, and a film-cutting step.

<Touch Panel Layer Formation Step>

First, on a surface (another surface) of a large glass substrate 110a (thickness approximately 0.7 mm×width approximately 300 mm×length approximately 400 nm) having a plurality of element formation regions arranged in a matrix, for example, a transparent conductive film such as an ITO (indium tin oxide) film is formed by sputtering to a thickness of approximately 100 nm. Then, by performing photolithography, etching, and resist removal on the transparent conductive film, the respective element formation regions have formed therein the first transparent electrodes 11, the first lead-out wiring lines 11a, and the second lead-out wiring lines 13a.

Then, on the entire substrate upon which the first transparent electrodes 11, the first lead-out wiring lines 11a, and the second lead-out wiring lines 13a are formed, an inorganic insulating film such as a silicon oxide film is formed by CVD (chemical vapor deposition), for example, to a thickness of approximately 300 nm, and by performing photolithography, etching, and resist removal on the inorganic conductive film, the interlayer insulating film 12 is formed in the respective element formation regions.

Then, on the entire substrate upon which interlayer insulating film 12 is formed, a transparent conductive film such as an ITO film is formed by sputtering, for example, to a thickness of approximately 100 nm, and then, photolithography, etching, and resist removal are performed on the transparent conductive film, thus forming the second transparent electrodes 13 in the respective element formation regions.

Lastly, on the entire substrate upon which the second transparent electrodes 13 are formed, a photosensitive acrylic resin film is coated by spin coating or slit coating, for example, to a thickness of approximately 2 μm, and by performing prebaking, exposure, developing, and postbaking on this coated film, the protective insulating film 14 is formed on the respective element formation regions, and as shown in FIG. 5(a), the touch panel layer 15 is formed in each element formation region.

<First Etching Step>

First, on a surface (another surface) of the glass substrate 110a on which the touch panel layer 15 is formed during the touch panel layer formation step, after coating an acrylic adhesive to a thickness of 2 μm to 15 μm, for example, a film 16 made of polypropylene, polyester, or the like (thickness approximately 50 μm×width approximately 400 mm×length approximately 500 mm) is formed on the adhesive such that the edge of the film 16 protrudes by approximately 50 mm from the edge of the glass substrate 110a (refer to FIG. 5(b).

Then, on the edge portion of the film 16 (up to approximately 30 mm in from the edge), an acrylic adhesive is coated to a thickness of approximately 2 μm to 15 μm, for example, and then, as shown in FIG. 5(b), a hard plate 17 (thickness approximately 0.5 mm to 2.0 mm×width approximately 400 mm×length approximately 500 mm) made of vinyl chloride, fiber-reinforced plastic, or the like is attached through the adhesive. In FIG. 5(b), a region A is a region of approximately 30 mm from the edge of the film 16 and the hard plate 17, and is an area where the film 16 and the hard plate 17 are bonded to each other. In the present embodiment, an example was shown of a manufacturing method in which the film 16 and the hard plate 17 are consecutively attached to the glass substrate 110a, but a manufacturing method may be used in which the film 16 and the hard plate 17 are bonded to each other at the edge portions thereof in advance, and the bonded film 16 and hard plate 17 are attached to the glass substrate 110a from the film 16 side.

In addition, by performing chemical etching using hydrofluoric acid on a surface (one surface) of the glass substrate 110a, the glass substrate 110a having the film 16 and the hard plate 17 attached thereto, the glass substrate 110a can be thinned to approximately 70 μm to 500 μm, for example, and as shown in FIG. 5(c), a thin glass substrate 110b is formed.

<Scribing Step>

By bringing in contact a blade tip of a super steel wheel, for example, to a surface (one surface) of the glass substrate 110b that has been thinned in the first etching step and rotating this super steel wheel, as shown in FIG. 5(d), scribe lines Ca for splitting the glass substrate 110b are formed in the surface of the glass substrate 110b. Here, the super steel wheel is a disc-shaped cutting blade made of a cemented carbide such as tungsten carbide, for example, and the side face of the disc protrudes in a tapered fashion towards the center of the thickness direction thereof.

<Second Etching Step>

By using hydrofluoric acid to perform chemical etching on a surface (one surface) of the glass substrate 110c into which the scribe lines Ca are formed in the scribing step, as shown in FIG. 5(e), the glass substrate 110c is thinned to approximately 30 μm to 300 μm, for example, and the scribe lines Ca are increased in size to scribe lines Cb, and through these scribe lines Cb, the glass substrate 110c is divided into respective element formation regions, thus forming a plurality of glass substrates 10.

FIG. 7 is a micrograph of an edge face of the glass substrate according to an example of the touch panel substrate of the present embodiment, and FIG. 8 is a micrograph of an edge face of a glass substrate of a comparison example thereof. If chemical etching is performed after forming the scribe lines as in the present embodiment, then as shown in FIG. 7, the surface of a scribe line C of the edge face of a glass G is smoothed, and thus, the edge face of the glass substrate is strengthened. By contrast, if scribe lines are formed after chemical etching for thinning is performed, then as shown in FIG. 8, scratches in the scribe line C in the edge face of the glass G remain, which means that the edge face of the glass substrate is weakened.

<Hard Plate Removal Step>

By cutting off a bonding portion A in the edge of the film 16 and the hard plate 17 in the intermediate body on which the glass substrates 10 are formed in the second etching step, as shown in FIG. 5(f), the hard plate 17 is removed and a film 16a is formed.

<Film-Cutting Step>

As shown in FIG. 5(g), after cutting the film 16a in the intermediate body on which the film 16a is formed in the hard plate removal step such that the film 16a is split for each glass substrate 10, the cut film 16b is removed.

In this manner, it is possible to manufacture the touch panel 20 of the present embodiment. After manufacturing the touch panel substrate 20, as shown in FIG. 6, a rigid transparent resin base material such as PET (polyethylene terephthalate) or PS (polystyrene) may be bonded on the rear surface thereof, for example.

As described above, according to the method of manufacturing the touch panel substrate 20 of the present embodiment, before forming the scribe lines Ca in the surface of the glass substrate 110b in order to split the glass substrate 110b in the scribing step, the first etching step is performed in which one surface of the glass substrate 110a is etched, thereby thinning the glass substrate 110a, and thus, in the second etching step, it is possible to reduce the degree to which the glass substrate 110c needs to be etched in order to split the glass substrate 110c through the scribe lines Ca (Cb). Thus, in the second etching step, when etching the surface of the glass substrate 110c in which the scribe lines Ca are formed, it is possible to reduce the amount of reaction product from etching filling the scribe line Ca, and thus, it is possible to split the glass substrate 110c reliably through the scribe lines Ca (Cb) formed in the surface of the glass substrate 110c. As a result, in the method of manufacturing the touch panel substrate 20, it is possible to split the glass substrate 110c reliably, and thus, it is possible to split the thin glass substrate reliably.

Also, according to the method of manufacturing the touch panel substrate 20 of the present embodiment, in the second etching step, the scribe lines Ca formed in the surface of the glass substrate 110c are made larger, and thus, scratches in the scribe lines Ca in the glass substrate 110c formed during the scribing step are reduced due to etching, thus making it possible to strengthen the edge faces of the split glass substrates 10.

Also, according to the method of manufacturing the touch panel substrate 20 of the present embodiment, in the first etching step, before etching one surface of the glass substrate 110a, the film 16 is attached to the other surface of the glass substrate 110a, thus making it more difficult to etch the other surface of the glass substrate 110a. In the scribing step, while the film 16 is attached to the other surface of the glass substrate 110b, scribe lines Ca are formed in the one surface of the glass substrate 110b, and in the subsequent second etching step also, the one surface of the glass substrate 110c is etched with the film 16 attached to the other surface of the glass substrate 110c. As a result, the glass substrate 110c is split along the scribe lines Ca (Cb), and the films 16 are attached to the separated glass substrates 10. In the film-cutting step, the film 16 is cut for each glass substrate 10 split during the second etching step, and thus, it is possible to separate the respective glass substrates 10 split during the second etching step.

Also, according to the method of manufacturing the touch panel substrate 20 of the present embodiment, in the first etching step, before etching the one surface of the glass substrate 110a but after attaching the film 16 on the other surface of the glass substrate 110a, the hard plate 17 is attached to the film 16, and thus, in the first etching step, the one surface of the glass substrate 110a is etched. Therefore, even if the glass substrate 110a becomes thin, it is possible to maintain the shape of the glass substrate 110b with the hard plate 17 attached to the film 16. Also, in the second etching step, even if the glass substrate 110b thinned during the first etching step is split, as a result of the hard plate 17 being attached to the film 16, the split glass substrates 10 are separate from each other, thus mitigating damage to the respective glass substrates 10. The hard plate removal step of removing the hard plate 17 is included between the second etching step and the film-cutting step, and thus, it is possible to cut the film 16 during the film-cutting step without the hard plate 17 being a physical obstruction.

Also, according to the method of manufacturing the touch panel substrate 20 of the present embodiment, in the first etching step, the film 16 and the hard plate 17 are formed larger than the glass substrate 110a in a plan view, and the hard plate 17 is attached to the film 16 by bonding the film 16 and the hard plate 17 to each other in an area further outside than the edge of the glass substrate 110a. Therefore, in the hard plate removal step, it is possible to remove the hard plate 17 from the film 16 attached to the other surface of the glass substrate 10 with ease by cutting off the bonding portion A between the film 16 and the hard plate 17 that protrudes from the glass substrate 110a.

### Embodiment 2

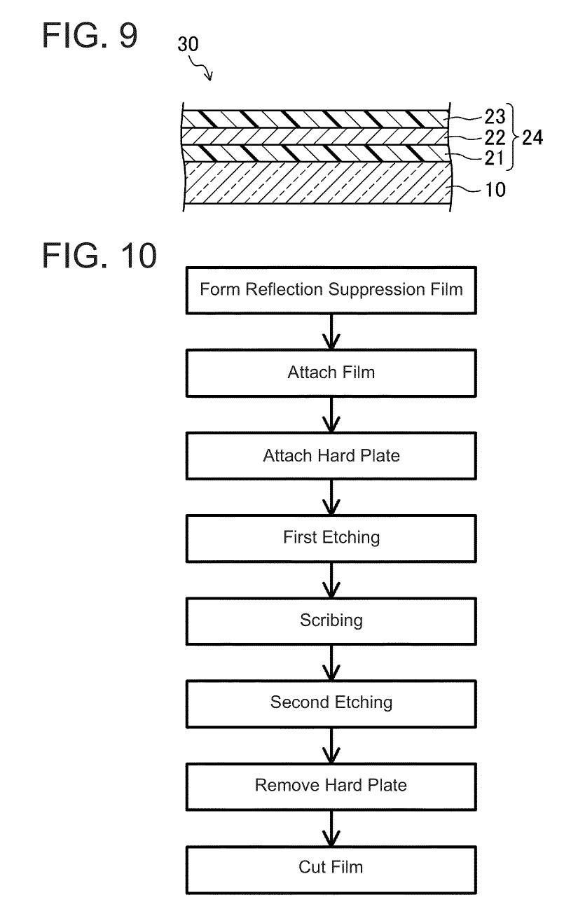

FIG. 9 is a cross-sectional view of a reflection suppression film substrate 30 of the present embodiment. FIG. 10 is a flow chart for manufacturing the reflection suppression film substrate 30. In each embodiment below, the same members as those in FIGS. 1 to 8 are given the same reference characters, and the descriptions thereof are not repeated.

In Embodiment 1, a method of manufacturing the touch panel substrate 20 was given as an example of a method of manufacturing the thin substrate, but in the present embodiment, a method of manufacturing the reflection suppression film substrate 30 will be given as an example.

As shown in FIG. 9, the reflection suppression film substrate 30 includes a glass substrate 10, and a reflection suppression film 24 provided as an element layer on the glass substrate 10.

As shown in FIG. 9, the reflection suppression film 24 includes a hard coat film 21 provided on the glass substrate 10, a low reflection film 22 provided so as to cover the hard coat film 21, and an antifouling coat film 23 provided so as to cover the low reflection film 22.

The hard coat film 21 is made of an acrylic resin or the like, for example.

The low reflection film 22 is made of a magnesium fluoride film, a silicon oxide film, or the like, for example.

The antifouling coat film 23 is made of fluorine-based resin film or the like, for example.

The reflection suppression film substrate 30 configured as described above mitigates reflection of external light by having light reflected off a boundary face between the hard coat film 21 and the low reflection film 22 interfere with light reflected off a boundary face between the low reflection film 22 and the antifouling coat film 23 so as to cancel each other out, which cancels out the amplitudes of the respective reflected beams of light.

Next, a method of manufacturing the reflection suppression film substrate 30 of the present embodiment will be described. Here, as shown in FIG. 10, the method of manufacturing the reflection suppression film substrate 30 of the present embodiment includes a step of forming the reflection suppression film, a first etching step that includes attaching a film and attaching a hard plate, a scribing step, a second etching step, a hard plate removal step, and a film-cutting step. However, the first etching step, the scribing step, the second etching step, the hard plate removal step, and the film-cutting step are substantially the same as the respective steps in Embodiment 1, and therefore, descriptions of such steps will be omitted, and the step of forming the reflection suppression film will be described.

<Step of Forming Reflection Suppression Film>

First, an acrylic resin film is coated onto a surface (another surface) of a large (thickness approximately 0.7 mm×width approximately 300 mm×length approximately 400 mm) glass substrate by spin coating or slit coating, for example, and then, this coated film is dried and baked, resulting in a hard coat film 21 approximately 10 μm in thickness being formed.

Next, on a surface (another surface) of the glass substrate upon which the hard coat film 21 is formed, a magnesium fluoride film, a silicon oxide film, or the like is formed by sputtering, for example, thus forming a low reflection film 22 approximately 100 nm to 250 nm in thickness.

In addition on a surface (another surface) of the glass substrate upon which the low reflection film 22 is formed, after coating a fluorine-based resin film by spin coating or slit coating, for example, this coated film is dried and baked, thus forming the antifouling film 23 approximately 3 nm in thickness.

It is possible to form the reflection suppression film 24 on the surface (another surface) surface of the glass substrate as described above, and then, it is possible to manufacture the reflection suppression film substrate 30 by performing, on the glass substrate upon which the reflection suppression film 24 is formed, the first etching step, the scribing step, the second etching step, the hard plate removal step, and the film-cutting step, which were described in Embodiment 1, in that order.

As described above, according to the method of manufacturing the reflection suppression film substrate 30 of the present embodiment, like Embodiment 1, the glass substrate is thinned in the first etching step before forming the scribe lines in the surface of the glass substrate during the scribing step, the glass substrate is thinned during the second etching step after the scribing step, and then the glass substrate is split along the scribe lines, and thus, it is possible to split the thin glass substrate reliably.

### Embodiment 3

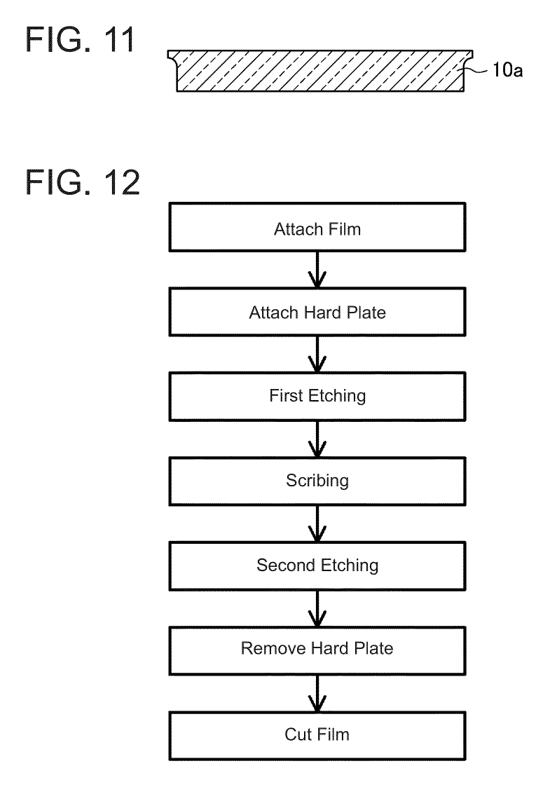

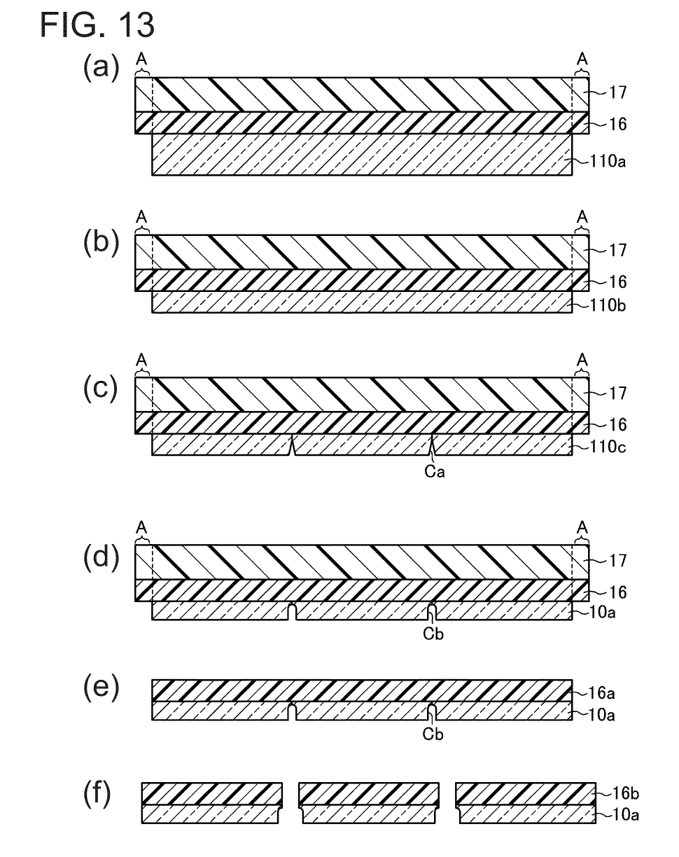

FIG. 11 is a cross-sectional view of a glass substrate 10a of the present embodiment. FIG. 12 is a flow chart for manufacturing the glass substrate 10a. FIG. 13 is a descriptive drawing showing cross-sections of a method of manufacturing the glass substrate 10a.

In Embodiments 1 and 2, the methods of manufacturing the touch panel substrate 20 and the reflection suppression film substrate 30 provided as element layers on the glass substrate were described as examples of a method of manufacturing the thin substrate, but in the present embodiment, an example of a method of manufacturing a glass substrate 10 that is not provided with an element layer will be described.

The glass substrate 10a is substantially the same as the glass substrate 10 of Embodiment 1, and as shown in FIG. 11, the edge portion thereof has an eve shape. In the glass substrate 10a, scratches in the scribe lines formed for splitting the substrate are reduced by chemical etching described later, and thus, the edge face is strengthened.

Next, a method of manufacturing the glass substrate 10a of the present embodiment will be described. Here, as shown in FIG. 12, the method of manufacturing the glass substrate 10a of the present embodiment includes a first etching step including attaching a film and attaching a hard plate, a scribing step, a second etching step, a hard plate removal step, and a film-cutting step.

<First Etching Step>

First, after coating an acrylic adhesive to a thickness of approximately 2 μm to 15 μm onto a surface (other surface) of a large (thickness approximately 0.7 mm×width approximately 300 mm×length approximately 400 mm) glass substrate 110a, for example, a film 16 (thickness approximately 50 μm×width approximately 400 mm×length approximately 500 mm) made of polypropylene, polyester, or the like is attached by the adhesive onto the glass substrate 110a such that the edge of the film 16 protrudes approximately 50 mm from the edge of the glass substrate 110a (refer to FIG. 13(a)).

Next, an acrylic adhesive is coated to a thickness of 2 μm to 15 μm, for example, onto the edge portion of the film 16 (up to approximately 30 mm from the edge), and then, as shown in FIG. 13(a), a hard plate 17 (thickness approximately 0.5 mm to 2.0 mm×width approximately 400 mm×length approximately 500 mm) made of vinyl chloride, fiber-reinforced plastic, or the like is attached to the film 16 by the adhesive.

A surface (one surface) of the glass substrate 110a to which the film 16 and the hard plate 17 are attached is chemically etched by hydrofluoric acid, and thus, the glass substrate 110a is thinned to approximately 70 μm to 500 μm, and as shown in FIG. 13(b), a thin glass substrate 110b is formed.

<Scribing Step>

By bringing in contact a blade tip of a super steel wheel, for example, on a surface (one surface) of the glass substrate 110b that has been thinned in the first etching step and rotating this super steel wheel, as shown in FIG. 13(c), scribe lines Ca for splitting the glass substrate 110b are formed in the surface of the glass substrate 110b.

<Second Etching Step>

By using hydrofluoric acid to perform chemical etching on a surface (one surface) of the glass substrate 110c into which the scribe lines Ca are formed in the scribing step, as shown in FIG. 13(d), the glass substrate 110c is thinned to approximately 30 μm to 300 μm in thickness, and the scribe lines Ca are increased in size to scribe lines Cb, and through these scribe lines Cb, the glass substrate 110c is split, thus forming a plurality of glass substrate 10.

<Hard Plate Removal Step>

By cutting off a bonding portion A in the edge of the film 16 and the hard plate 17 in the intermediate body on which the glass substrates 10a are formed in the second etching step, as shown in FIG. 13(e), the hard plate 17 is removed and a film 16a is formed.

<Film-Cutting Step>

As shown in FIG. 13(f), after the film 16a on an intermediate body having the film 16a formed during the hard plate removal step is split for each of the glass substrates 10a, the split films 16b are removed.

In this manner, it is possible to manufacture the glass substrate 10a of the present embodiment.

As described above, according to the method of manufacturing the glass substrate 10a of the present embodiment, like Embodiments 1 and 2, the glass substrate 110a is thinned in the first etching step before forming the scribe lines Ca in the surface of the glass substrate 110b in the scribing step, the glass substrate 110c is thinned in the second etching step after the scribing step, and then the glass substrate 110c is split along the scribe lines Ca (Cb), and thus, it is possible to split the thin glass substrate 110c reliably.

In the embodiments above, as a method of manufacturing a thin substrate, examples were shown of methods of manufacturing a touch panel substrate, a reflection suppression film substrate, and a glass substrate, but the present invention can be applied to a method of manufacturing a thin substrate having formed thereon another type of element layer.

### INDUSTRIAL APPLICABILITY

As described above, in the present invention, it is possible to split the thin glass substrate reliably, and thus, the present invention is useful for a touch panel for which a thin profile and lighter weight are in demand, and for an electronic device having a touch panel.

### DESCRIPTION OF REFERENCE CHARACTERS

Ca, Cb scribe line
10, 110a to 110c glass substrate
10a glass substrate (thin substrate)
15 touch panel layer (element layer)
16 film
17 hard plate
20, 20a touch panel substrate (thin substrate)
24 reflection suppression film (element layer)
30 reflection suppression film substrate (thin substrate)

1. A method of manufacturing a thin substrate, comprising:
a first etching step of etching one surface of a glass substrate and thereby thinning the glass substrate;
a scribing step of forming a scribe line in a surface of the thinned glass substrate; and
a second etching step of etching the surface of the glass substrate in which the scribe line is formed to thin the glass substrate and deepen the scribe lines so that the glass substrate is split along the scribe line into a plurality of substrates.

2. The method of manufacturing a thin substrate according to claim 1,
wherein, in the first etching step, a film is attached to another surface of the glass substrate before etching the one surface of the glass substrate,
wherein, in the scribing step, the scribe line is formed in the one surface of the glass substrate, and
wherein a film-cutting step of cutting the film such that said film is provided for each of the plurality of separated substrates is included after the second etching step.

3. The method of manufacturing a thin substrate according to claim 2,
wherein, in the first etching step, before etching the one surface of the glass substrate but after the film is attached to said another surface of the glass substrate, a hard plate is attached to the film, and
wherein, a hard plate removal step of removing the hard plate is included between the second etching step and the film-cutting step.

4. The method of manufacturing a thin substrate according to claim 3,
wherein the film and the hard plate are formed so as to be larger than the glass substrate in a plan view,
wherein, in the first etching step, the hard plate is attached to the film by the film and the hard plate being bonded to each other in a bonding portion outside of an edge of the glass substrate, and
wherein, in the hard plate removal step, the hard plate is removed by cutting off the bonding portion between the film and the hard plate.

5. The method of manufacturing a thin substrate according to claim 1, wherein an element layer forming step of forming a plurality of element layers respectively split along with the glass substrate in the second etching step on said another surface of the glass substrate is included before the first etching step.

6. The method of manufacturing a thin substrate according to claim 5, wherein the plurality of element layers are respectively touch panel layers functioning as touch panels.

7. The method of manufacturing a thin substrate according to claim 5, wherein the plurality of element layers are reflection suppression films, respectively formed integrally.
